(19) United States
(12) Patent Application Publication
(10) Pub. No.: US 2025/0070726 A1
(43) Pub. Date: Feb. 27, 2025

(54) Amplifier Auto-Zero Without Signal Switching

(71) Applicant: SiliconIntervention Inc., Kelowna (CA)

(72) Inventor: A. Martin Mallinson, Kelowna (CA)

(21) Appl. No.: 18/807,848

(22) Filed: Aug. 16, 2024

Related U.S. Application Data
(60) Provisional application No. 63/534,481, filed on Aug. 24, 2023.

(51) Int. Cl. H03F 3/04

(52) U.S. Cl. CPC H03F 3/04; H03F 2200/372; H03F 2200/375

(57) ABSTRACT

An apparatus for removing noise due to a DC offset voltage from the frequency band of interest of a signal. Input noise errors are moved out of the band of interest by changing the noise gain of the system without placing a switch in the signal path. The resistance through which an input signal passes to the amplifier remains unchanged, but the noise gain is selectively changed by use of a single switch that inserts an additional resistance from a zero signal source in response to a switching signal, thus switching the amplifier between two states with different noise gains. The output signal may be passed through a sigma-delta modulator and an exclusive-or gate clocked at a duty cycle such that the signal gain of the amplifier is unchanged while the different noise gain states cancel out, thus relocating the input noise errors to harmonic frequencies of the switching signal.

This application claims priority from Provisional Application No. 63/534,481 filed Aug. 24, 2023, which is incorporated by reference herein in its entirety.

### FIELD OF THE INVENTION

The present invention relates generally to amplifier circuits, and more particularly to removing low frequency noise and noise due to a direct current (“DC”) offset voltage from the frequency band of a signal.

### BACKGROUND OF THE INVENTION

A differential (or difference) amplifier is a two-input circuit that amplifies the difference between its two inputs. An operational amplifier (or “op-amp”) is an example of a differential amplifier. (In some instances, a differential amplifier may be used to amplify a single input, with one of the inputs to the amplifier connected to a ground.) Such amplifiers are used in a wide variety of applications.

FIG. 1 is a diagram of a differential amplifier circuit 100 that includes an op-amp A0. Circuit 100 receives an input signal in the form of two inputs In and its inverse, In-bar, which are received by non-inverting and inverting inputs of op-amp A0 through two input resistors having the same value R1. The outputs Out and Out-bar are fed back to the inputs through two feedback resistors having the same value R2. As is well known in the art, the gain of circuit 100 is the ratio of the values of the resistors, R2/R1, and thus circuit 100 will cause a signal between In and In-bar to appear as a signal between Out and Out-bar after being amplified by a signal gain of R2/R1. As above, this assumes an ideal op-amp in which only the input signal is amplified. (While resistors are used herein to illustrate the relevant circuits, one of skill in the art will appreciate that any two-port device with resistance may be used; thus, resistors, capacitors, inductors and other resistive devices may be used.)

Ideally, it is desirable that a differential amplifier amplify only an applied input signal that creates a difference between the two inputs of the amplifier. However, in many cases the physical construction of the amplifier results in an DC offset voltage between the two inputs of the amplifier that is amplified along with the desired signal. Any DC offset voltage, as well as any low frequency noise present in that DC offset voltage, will also be amplified by circuit 100.

FIG. 2 is another diagram of an amplifier circuit 200 that is similar to circuit 100 of FIG. 1 but explicitly shows the presence of an offset voltage V, which is modeled as a voltage source on the non-inverting input of the op-amp A0. Since the offset voltage is modeled as being applied to only one of the inputs of op-amp A0, as is known in the art the gain applied to the offset voltage V and to other low frequency noise (known as the “noise gain”) is not the same gain of R2/R1 applied to the input signal, but rather is −(R1+R2)/R1.

One of skill in the art will appreciate that there is a well-known technique for dealing with the low frequency and DC components of noise in an amplifier circuit such as that of FIGS. 1 and 2. A circuit for performing this technique is known as an “auto-zero” circuit, and effectively employs a number of switches to reverse the signal to amplifier connections in such a way as to move the low frequency and DC noise components into a different frequency band.

However, as will be seen, such a circuit has other disadvantages and artifacts that can disturb and degrade the input signal. It would be advantageous to be able to achieve the benefits of the auto-zero technique without having switches in the signal path or reversing the input signal.

### SUMMARY OF THE INVENTION

Described herein is an apparatus for removing noise due to a DC offset voltage from the frequency band of a signal without reversing the input signal.

One embodiment discloses a circuit for removing noise due to a DC offset voltage in an amplifier from a signal frequency band, comprising: an amplifier having a non-inverting input, an inverting input, and an output, the non-inverting input connected to a ground; a first resistive device having a first end configured to receive an input signal in the signal frequency band and a second end connected to the inverting input of the amplifier; a second resistive device having a first end connected to the output of the amplifier and a second end connected to the inverting input of the amplifier; a third resistive device having a first end connected to the inverting input of the amplifier and a second end; a two-position switch having a first end connected to the second end of the third resistive device and a second end connected to a ground, whereby the second end of the third resistive device is connected through the two-position switch to the ground when the switch is in a first position and not connected through the two-position switch to the ground when the switch is in a second position; a single-bit sigma-delta modulator having an input connected to the output of the amplifier and an output, and configured to receive a sequence of clock edges and output a sequence of bits in response to the sequence of edges of a clock signal; an exclusive-or element having a first input connected to the output of the sigma-delta modulator, a second input, and an output; a switching signal source connected to the two-position switch and to the second input of the exclusive-or element and configured to provide a switching signal that opens and closes the two-position switch at a switching frequency not in the signal frequency band; whereby any noise due to the DC offset voltage in the amplifier is moved out of the signal frequency band and to the switching frequency and harmonics thereof.

Another embodiment discloses a circuit for removing noise due to a DC offset voltage in an amplifier from a signal frequency band, comprising: an amplifier having a non-inverting input, an inverting input, a non-inverted output and an inverted output; a first resistive device having a first end configured to receive an input signal in the signal frequency band and a second end connected to the non-inverting input of the amplifier; a second resistive device having a first end configured to receive an inverse of the input signal and a second end connected to the inverting input of the amplifier; a third resistive device having a first end connected to the inverted output of the amplifier and a second end connected to the non-inverting input of the amplifier; a fourth resistive device having a first end connected to the non-inverted output of the amplifier and a second end connected to the inverting input of the amplifier; a fifth resistive device having a first end connected to the non-inverting input of the amplifier and a second end; a two-position switch having a first end connected to the second end of the third resistive device and a second end connected to the inverting input of the amplifier, whereby the second end of the third resistive device is connected through the two-position switch to the inverting input of the amplifier when the switch is in a first position and not connected through the two-position switch to the inverting input of the amplifier when the switch is in a second position; a single-bit sigma-delta modulator having a first input connected to the inverted output of the amplifier, a second input connected to the non-inverted output of the amplifier, and an output, and configured to receive a sequence of clock edges and output a sequence of bits in response to the sequence of edges of a clock signal; an exclusive-or element having a first input connected to the output of the sigma-delta modulator, a second input, and an output; a switching signal source connected to the two-position switch and to the second input of the exclusive-or element and configured to provide a switching signal that opens and closes the two-position switch at a switching frequency not in the signal frequency band; whereby any noise due to the DC offset voltage in the amplifier is moved out of the signal frequency band and to the switching frequency and harmonics thereof.

Yet another embodiment discloses a circuit for removing noise due to a DC offset voltage in an amplifier from a signal frequency band, comprising: an amplifier having a non-inverting input, an inverting input, and an output, the non-inverting input connected to a ground; a first resistive device having a first end configured to receive an input signal in the signal frequency band and a second end connected to the inverting input of the amplifier; a second resistive device having a first end connected to the output of the amplifier and a second end connected to the inverting input of the amplifier; a third resistive device having a first end connected to the inverting input of the amplifier and a second end; a two-position switch having a first end connected to the second end of the third resistive device and a second end connected to a ground, whereby the second end of the third resistive device is connected through the two-position switch to the ground when the switch is in a first position and not connected through the two-position switch to the ground when the switch is in a second position; a switching signal source connected to the two-position switch and configured to provide a switching signal that opens and closes the two-position switch at a switching frequency not in the signal frequency band; whereby any noise due to the DC offset voltage in the amplifier is moved out of the signal frequency band and to the switching frequency and harmonics thereof.

Still another embodiment discloses a circuit for removing noise due to a DC offset voltage in an amplifier from a signal frequency band, comprising: an amplifier having a non-inverting input, an inverting input, a non-inverted output and an inverted output; a first resistive device having a first end configured to receive an input signal in the signal frequency band and a second end connected to the non-inverting input of the amplifier; a second resistive device having a first end configured to receive an inverse of the input signal and a second end connected to the inverting input of the amplifier; a third resistive device having a first end connected to the inverted output of the amplifier and a second end connected to the non-inverting input of the amplifier; a fourth resistive device having a first end connected to the non-inverted output of the amplifier and a second end connected to the inverting input of the amplifier; a fifth resistive device having a first end connected to the non-inverting input of the amplifier and a second end; a two-position switch having a first end connected to the second end of the third resistive device and a second end connected to the inverting input of the amplifier, whereby the second end of the third resistive device is connected through the two-position switch to the inverting input of the amplifier when the switch is in a first position and not connected through the two-position switch to the inverting input of the amplifier when the switch is in a second position; an adder configured to combine the inverting and non-inverting outputs of the amplifier; a switching signal source connected to the two-position switch and configured to provide a switching signal that opens and closes the two-position switch at a switching frequency not in the signal frequency band; whereby any noise due to the DC offset voltage in the amplifier is moved out of the signal frequency band and to the switching frequency and harmonics thereof.

### BRIEF DESCRIPTION OF THE DRAWINGS

FIG. 1 is a diagram of a differential amplifier circuit as is known in the prior art.

FIG. 2 is diagram of a differential amplifier circuit showing the practical effect of an offset voltage as is known in the prior art.

FIG. 3 is a diagram of a single-ended amplifier circuit as is known in the prior art.

FIG. 4 is diagram of an auto-zero amplifier circuit that includes a differential amplifier and auto-zero circuitry as is known in the prior art.

FIG. 5 is a diagram of one embodiment of a differential amplifier circuit according to the present approach.

FIG. 6 is a diagram of one embodiment of a single-ended amplifier circuit according to the present approach.

FIG. 7 is a diagram of another embodiment of a differential amplifier circuit according to the present approach.

FIG. 8 is a diagram of another embodiment of a single-ended amplifier circuit according to the present approach.

FIG. 9 is a diagram of another embodiment of a differential amplifier circuit according to the present approach.

FIG. 10 is a diagram of another embodiment of a single-ended amplifier circuit according to the present approach.

### DETAILED DESCRIPTION OF THE INVENTION

Described herein is an apparatus for removing noise due to a DC offset voltage from the frequency band of a signal. The present approach seeks to improve upon the noise performance of prior art auto-zero circuits by moving input noise errors out of the band of interest by changing the noise gain of the system without the use of any switches in the signal path. Additionally, certain forms of an Analog to Digital Converter (“ADC”) can be augmented to include the noise gain changing aspect of the present approach with a resistor, switch and XOR gate.

In the present approach, the resistance through which an input signal passes to the amplifier is selectively changed by use of a single switch in response to a switching signal, thus switching the amplifier between two states with different noise gains. The output signal may be passed through a sigma-delta modulator and an exclusive-or gate clocked at a duty cycle such that the signal gain of the amplifier is unchanged while the different noise gain states cancel out, thus relocating the input noise errors to harmonic frequencies of the switching signal.

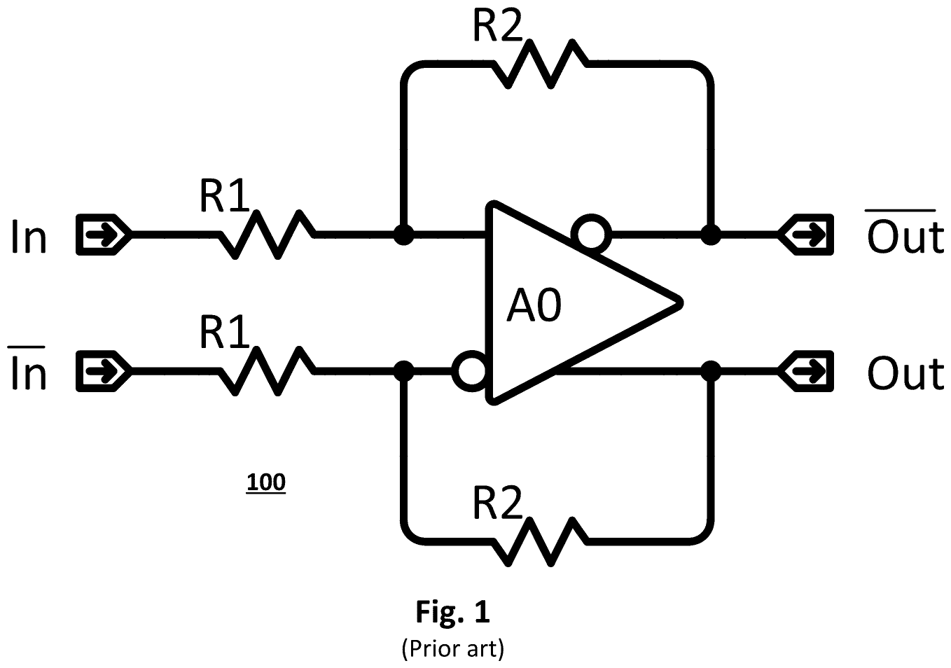

As above, FIG. 1 is a diagram of a differential amplifier circuit 100 that includes an op-amp A0 as is known in the prior art. In the configuration illustrated, circuit 100 receives an input signal in the form of two inputs In and its inverse, In-bar, which are received by non-inverting and inverting inputs of op-amp A0 through two resistors having the same value R1. The outputs Out and Out-bar are fed back to the inputs through two resistors having the same value R2. As is well known in the art, with an ideal op-amp, the gain of circuit 100 by which the input signal is amplified is the ratio of the values of the resistors, R2/R1.

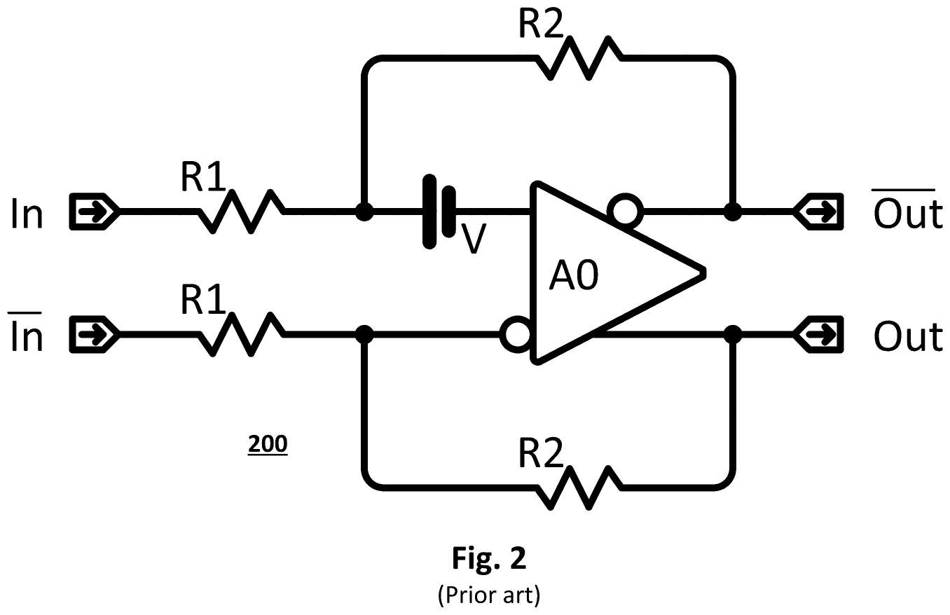

Again, in practice the actual construction of an op-amp results in a DC offset voltage between the two inputs to the op-amp. FIG. 2 again is a diagram of a differential amplifier circuit 200 as is known in the art; circuit 200 is similar to circuit 100 of FIG. 1 but explicitly demonstrates the presence of an offset voltage V, which is implicit in circuit 100. The offset voltage is modeled as a voltage source applying a voltage to the non-inverting input of the op-amp A0. Since the offset voltage is modeled as being applied to only one of the inputs of op-amp A0, as is known in the art the noise gain applied to the offset voltage V is not the same gain of R2/R1 applied to the input signal, but rather is −(R1+R2)/R1.

The term “noise gain” is commonly used by analog circuit designers, and serves as a reminder that the offset voltage is just the DC component of the noise of the amplifier elements as compared to the input signal. It is well known that it is common for an amplifier to also exhibit low frequency noise of a magnitude that is inversely related to the frequency of the noise, sometimes called 1/F noise, F being the frequency of each component of the low frequency noise.

In the circuit diagrams discussed below, it is understood that an offset voltage will typically be present but, as in FIG. 1 above, is not explicitly represented by a voltage source.

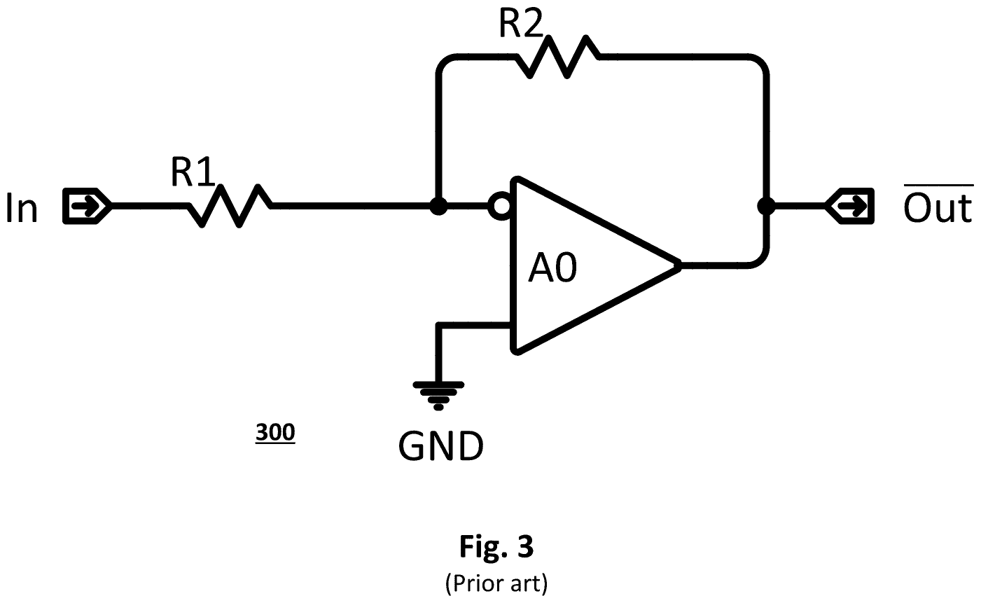

As above, in some instances a differential amplifier may be used to amplify a single input, with one of the inputs to the amplifier connected to a ground. FIG. 3 is a diagram of a single-ended amplifier circuit 300 as is known in the prior art. In operation, it acts in a similar fashion to circuit 100 of FIG. 1, amplifying the input signal In by R2/R1 while the noise gain is again −(R1+R2)/R1. Amplifier A0 here produces only a single inverted output Out-bar.

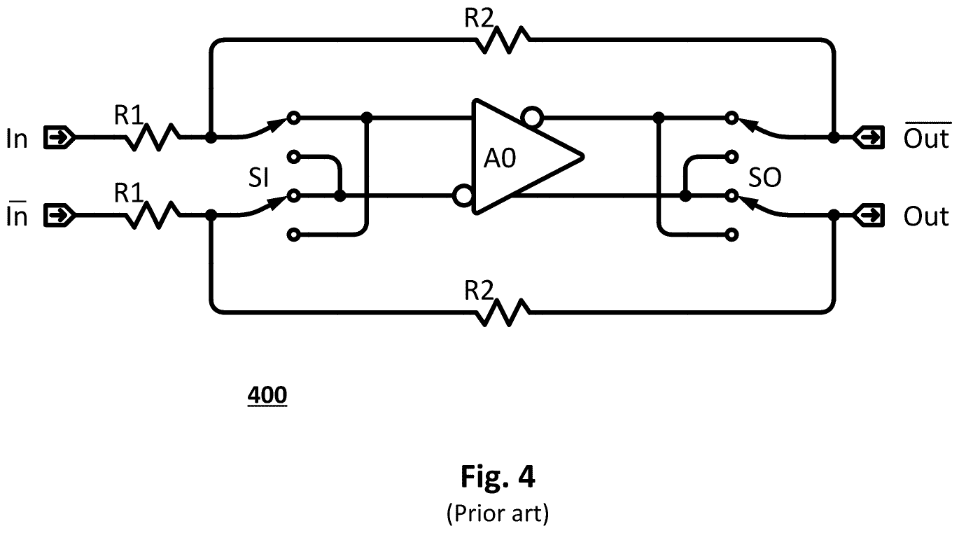

FIG. 4 is diagram of an auto-zero amplifier circuit 400 that includes a differential amplifier and auto-zero circuitry as is known in the prior art. As above, an auto-zero circuit is a well-known technique for dealing with the low frequency and DC components of noise in amplifier circuits such as those of FIGS. 1 and 2.

It may be seen that circuit 400 is similar to circuit 100 of FIG. 1, with the addition of two single-pole-double-throw (“SPDT”) switches SI and two SPDT switches SO. As illustrated in FIG. 4, with switches SI and SO in the positions shown, the connections of input signals In and In-bar to amplifier A0 and the output signals Out and Out-bar are the same as in circuit 100 of FIG. 1.

Changing switches SI to their opposite positions will be seen to reverse the connections of input resistors R1 and feedback resistors R2 to amplifier A0, such that input signal In will connect to the inverting input of amplifier A0 instead of the non-inverting input, and input signal In-bar will connect to the non-inverting input of amplifier A0 instead of the inverting input. Changing switches SO to their opposite positions will have a similar effect of changing the outputs of amplifier A0. Thus, changing all four switches to their opposite positions at the same time keeps the feedback negative and the signal gain at R2/R1, and both states of the switches are stable.

As above, when switches SI and SO are in the position shown in FIG. 4, the noise gain of the offset voltage and 1/F noise is −(R1+R2)/R1, as in FIG. 1. However, when all of the switches change position, the noise gain becomes (R1+R2)/R1, i.e., the sign of the gain changes. Thus, if the switches are all continuously switched synchronously at a 50:50 duty cycle, the average value of the noise gain will be zero, since half of the time the noise gain will be −(R1+R2)/R1 and the other half of the time the noise gain will be (R1+R2)/R1, and the average value of the output will not contain any artifact due to the offset voltage or low frequency noise.

There is one condition to this, however; the noise (the 1/F noise and the noise due to the input error voltage of the amplifier) has not disappeared; rather, it is still present in the output as a signal that alternates between positive and negative at the rate of operation of the switches. The effect of the switching is to move the noise in the frequency domain to frequencies that surround the frequency of operation of the switches. For example, if the switches are operated at 1 kilohertz (“kHz”), the output spectrum will contain a series of harmonics of 1 kHz, the amplitudes of which add up to the value of the noise gain times the input noise. The auto-zero technique is thus best appreciated as a shifting of the 1/F noise and the noise of the amplifier in the frequency domain, rather than a complete removal of that noise.

Thus, for the average value of the output to have no error, the process of averaging the output must occur over a frequency band that does not contain the shifted DC and 1/F noise. This is usually the case since near-DC signals are easily filtered out, far from, for example, shifted noise at 1 kHz; for example, a digital voltmeter may measure at a rate of ten samples per second, thus using filtering of the band from DC to 10 Hz.

The frequency shifting nature of an auto-zero circuit leads to the further observation that while the troublesome DC offset and the low frequency 1/F noise are indeed removed from the band that will be averaged, any input noise that the amplifier has near the switching frequency is moved into the band being averaged.

For this reason, the auto-zero technique only works well if the amplifier has low noise near the switching frequency and a higher and troublesome noise in the low frequencies. This is usually the case: an amplifier typically exhibits a transition to an ever-increasing noise (the 1/F noise) as the frequency tends to zero. A graph of this 1/F characteristic then intercepts a flat noise of the amplifier, which is typically frequency independent thermal noise up to the bandwidth limit of the amplifier. For example, in an audio amplifier beginning at 10 Hz the noise will be high since 10 Hz is in the 1/F region of the amplifier. As the frequency increases this 1/F noise falls, and, in a typical case, at about 1 kHz the noise ceases to fall as the 1/F noise intercepts the flat noise which is equal at all frequencies.

If the auto-zero switching frequency is in the flat band region of the system, it will remove 1/F and DC errors and leave a low frequency error equal to only the flat band noise of the amplifier. This is typically a significant improvement.

In addition to these issues, one of skill in the art will appreciate that the presence of the switches SI and SO in the signal path is detrimental to the performance of circuit 400 because they cause artifacts in several ways. First, an ideal switch has no resistance when on, and thus should appear to be at zero ohms, and infinite resistance when off; in practice, switches are often not perfect, and thus the gain R2/R1 may be imprecise since the actual non-zero resistance when the switch is on adds to the resistor values. In addition, a pair of switches cannot precisely switch at the same time, thus causing either a momentary short (both switches on) or a momentary open-circuit (both switches off), which can significantly disturb the source driving the input and spoil the precise gain. Finally, there can be an interaction, usually a capacitive coupling, between the control signal and the terminal of the switch, which results in the control signal coupling into the signal being processed, causing a further artifact.

The present approach provides an alternate way to achieve the benefit of the prior art auto-zero technique without the reversal of the amplifier connections, and thus without the switches SI and SO. In the present approach, the signal is not disturbed or degraded by the presence of the switches and action of reversal, thus improving performance. Further, in use with a single-bit ΣΔ modulator the present approach uses far fewer components that the reversing switch circuit.

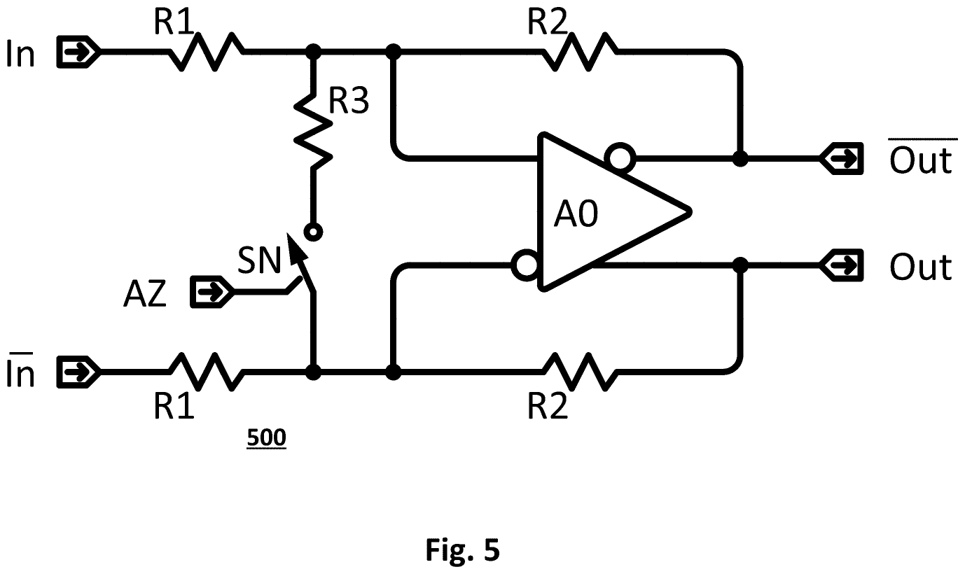

FIG. 5 is a diagram of one embodiment of a differential amplifier circuit according to the present approach. In circuit 500, as in circuit 100 of FIG. 1 and circuit 400 of FIG. 4 discussed above, inputs In and In-bar are received by amplifier A0 through resistors with a value of R1. Outputs Out and Out-bar are fed back to amplifier A0 through resistors with a value of R2. Thus, the gain applied to the input signal by circuit is again R2/R1.

Another resistor with a value R3 is located such that it can be connected to or disconnected from the inputs to amplifier A0 by means of a switch SN that is activated by a switching signal AZ; with switch SN in the open position as shown, the noise gain is again −(R1+R2)/R1 as in FIGS. 1 and 4.

However, if switch SN is closed, the effective resistance through which each input signal In and In-bar passes is no longer R1; rather, R1 is now in parallel with half of R3 and the input resistance may be written as R1∥R3/2. (This may be seen by considering R3 as two resistors of R3/2 in series, with a ground in between them. When determining the noise gain calculation, the inputs In and In-bar may also be assumed to be grounded.)

Instead of −(R1+R2)/R1, the noise gain now becomes:

$$- ( ( R 1 \vert \vert R 3 / 2 ) + R 2 ) / ( R 1 \vert \vert R 3 / 2 )$$

The signal gain of R2/R1 does not change when switch SN is opened or closed.

To simplify analysis, assume that the values R1=R2=R3/2. In this case the signal gain is unity and the noise gain if SN is open is two. Closing SN changes the noise gain to three. Thus, the signal and the noise are distinguished, as the signal output remains the same, but the noise output varies from minus two times its value to three times its value depending upon the state of switch SN.

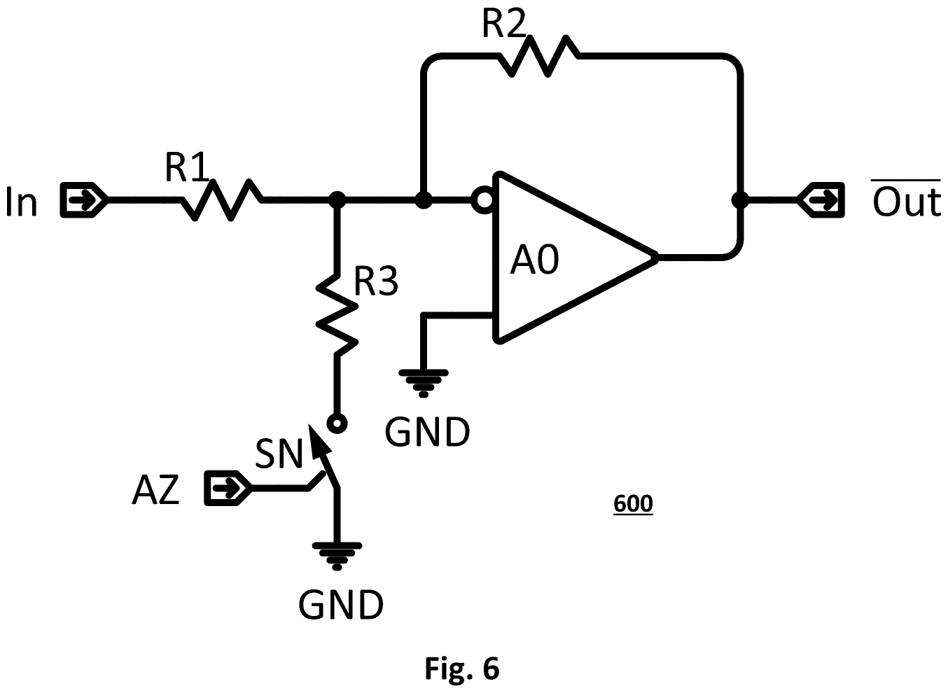

FIG. 6 is a diagram of one embodiment of a single-ended amplifier circuit according to the present approach. Circuit 600 is the single-ended version of circuit 500 of FIG. 5. Note that in circuit 600 closing switch SN places resistor R1 in parallel with R3 and not R3/2 because R3 only connects to one input of amplifier A0. Thus, if R1=R2=R3 in circuit 600 (rather than R3/2 as in circuit 500), the signal gain is again unity, and the noise gain is still minus 2 when switch SN is open and three when switch SN is closed.

Using this analysis, it is possible to construct a circuit in which switch SN is activated in such a way as to achieve the same effect as that of circuit 400 of FIG. 4 discussed above.

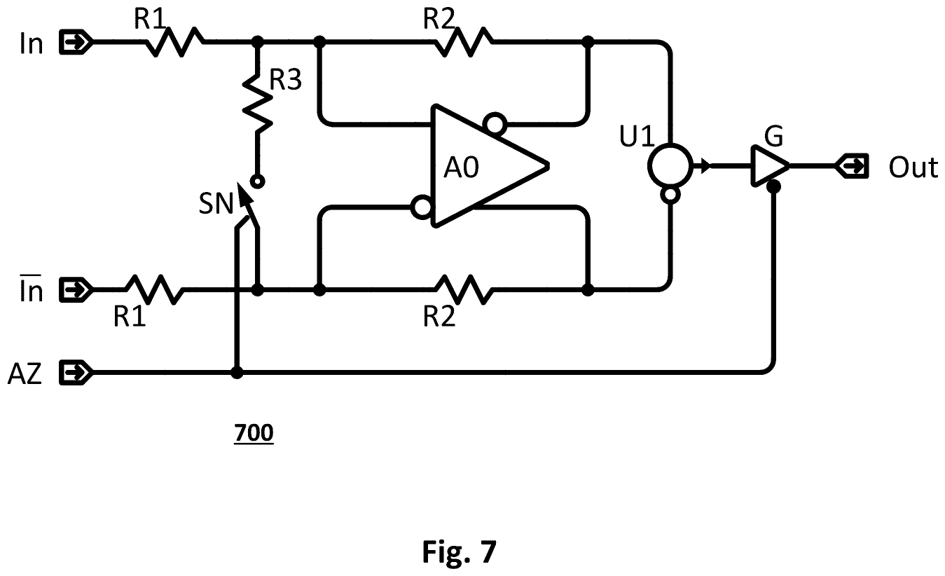

FIG. 7 is a diagram of another embodiment of a differential amplifier circuit according to the present approach. Circuit 700 includes the circuit elements of circuit 500; in addition, an adder U1 combines the outputs from amplifier A0 (called Out and Out-bar above) to produce the single-ended output signal from the differential outputs, and a gain element G then multiplies the single-ended output signal to produce the final output signal Out. Gain element G has two different gain states, and is activated by the same signal AZ that activates switch SN.

Suppose that the signal AZ causes both switch SN and gain element G to switch at a rate of 100 kHz. As above, if R1=R2=R3/2, the signal gain is unity and the noise gain is two if SN is open and three if SN is closed. If the gain of gain element G is set to 3 when SN is open, the output will contain six times the input noise of the amplifier; setting the gain to minus 2 when SN is closed will also result in six times the input noise of the amplifier, but with the opposite sign.

If signal AZ runs at this rate as in the prior art auto-zero methods, circuit 700 will produce an output with an average noise of zero, just as in circuit 400 discussed above; the noise is removed from the output signal as in the prior art, but without the input switching of circuit 400.

Meanwhile, the signal gain through amplifier A0 is unity whether switch SN is open or closed. The output signal is then also passed through gain element G, and moves from minus two times its nominal output to plus three times its nominal output, and thus the average value of Out is not zero but the same unity output that is produced by amplifier A0.

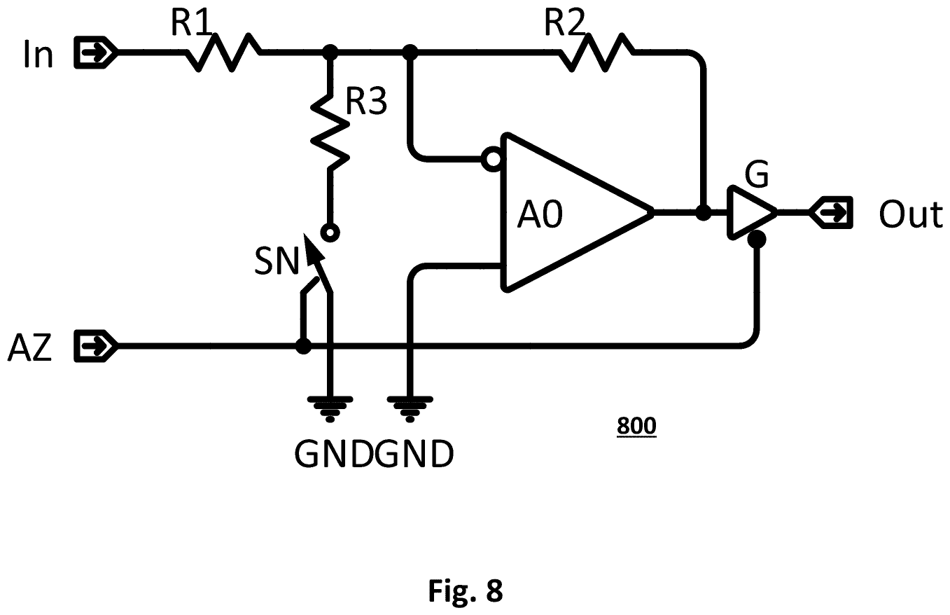

FIG. 8 is a diagram of another embodiment of a single-ended amplifier circuit according to the present approach. Circuit 800 is the single-ended version of circuit 700, again with the difference that R1=R2=R3 in circuit 800, rather than R3/2 as in circuit 700. The adder U1 of circuit 700 is not needed since amplifier A0 again has only a single output. The description of circuit 700 otherwise applies to circuit 800 as well.

While FIGS. 7 and 8 demonstrate the principle of the present approach, it may not be convenient to create a controlled multiplier as shown. However, there may be cases where an analog circuit is desirable; in such instances it may be possible to build a circuit such as circuits 700 and 800 of FIGS. 7 and 8, respectively, without the gain element G, leaving the problem of changing the gain to a subsequent stage, after the circuit has used the auto-zero function to remove noise as described herein.

Still, in many situations, the present approach may be best utilized as part of an ADC where the output is digital, and the difference of the differently weighted outputs is calculated in the digital domain.

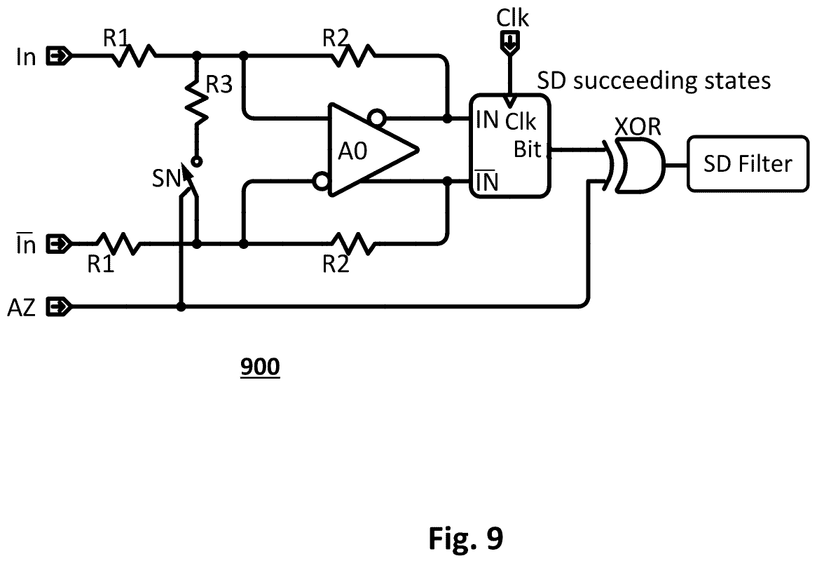

FIG. 9 is a diagram of another embodiment of a differential amplifier circuit according to the present approach. Circuit 900 includes a simplified and useful implementation of the present approach in which the amplifier A0 is the first stage of a single bit ΣΔ modulator.

In the discussion of FIG. 7 and the previous discussion it was assumed that the signal AZ is high and low with a 50:50 duty cycle, and that the difference operation on the output is weighted in proportion to the inverse of the two noise gain states. Alternatively, it is possible to change the duty cycle of the signal AZ such that it remains in each state in proportion to differing noise gains of that state.

For example, in circuit 700 of FIG. 7, if AZ is low (SN open) a noise gain of two is present, while if AZ is high (SN closed) a noise gain of three is present. If the duty cycle of AZ is adjusted to be low for three time intervals and high for two time intervals then the average difference of the output requires no weighting. The time spent in each noise gain state can replace the need to weight the outputs prior to subtracting them.

Circuit 900 illustrates how varying the duty cycle simplifies using the present approach with a single bit sigma-delta modulator. Amplifier A0 forms the input stage to a single-bit sigma-delta modulator SD. The output bit from SD and the switching signal AZ are fed to an exclusive-or (XOR) gate, and the output of the XOR gate is then filtered by a sigma-delta filter to reconstruct the output signal.

The low time of AZ is proportional to the noise gain when it is high, the high time of the AZ signal is proportional to the noise gain when it is low. Thus, the change of gain of circuit 700 in FIG. 7 is accomplished due to the non-50:50 duty cycle and the subtraction is accomplished with the XOR gate.

The changing noise gain of the amplifier circuit as described above is added to the SD filter when AZ is low and subtracted when SD is high; this is because in a single-bit sigma-delta modulator output stream inversion of the bit changes the sign of the signal.

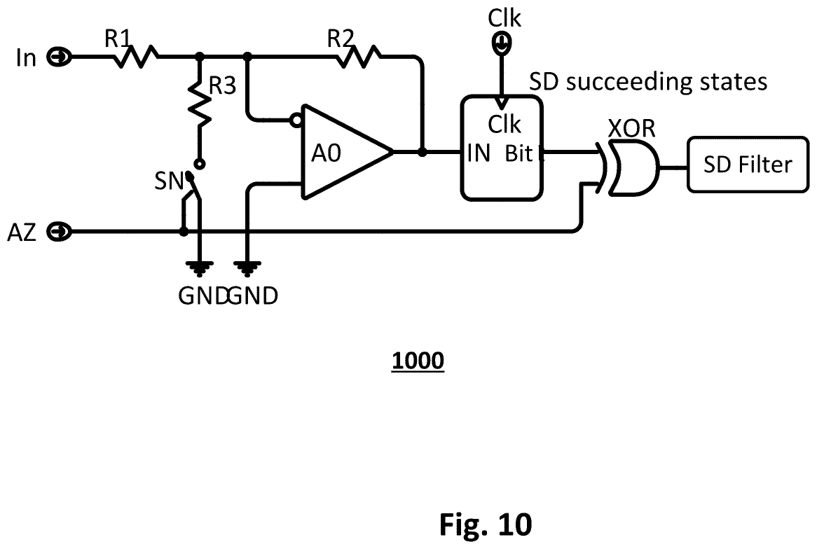

FIG. 10 is a diagram of another embodiment of a single-ended amplifier circuit under the present approach. Circuit 1000 is the single-ended version of circuit 700, again with the difference that R1=R2=R3 in circuit 800, rather than R3/2 as in circuit 900. As is apparent, SD now has only one input since amplifier A0 produces only one output.

The values of the noise gain are somewhat arbitrary but cannot be unity. They could even be as high as, for example, 100, although there is no practical point to making them that high. In general, it is desirable to keep the noise gains low but different enough to get a maximum change yet still allow the duty cycle to be adjusted to cause them to cancel out as described above. As long as the noise gains are different enough, the present approach will work; as explained above, the noise gains of 2 and 3 described above will obtain the desired results.

Using the present approach, input errors may thus be moved out of the band of interest by changing the noise gain of the system. The noise gain can be changed without the use of any switches in the signal path. Additionally, certain forms of an ADC can be augmented to include the noise gain changing aspect of the present approach with a resistor, switch and XOR gate.

The disclosed system has been explained above with reference to several embodiments. Other embodiments will be apparent to those skilled in the art in light of this disclosure. Certain aspects of the described method and apparatus may readily be implemented using configurations other than those described in the embodiments above, or in conjunction with elements other than or in addition to those described above. For example, as is well understood by those of skill in the art, various choices will be apparent to those of skill in the art, such as resistor values, gain, switching speeds, frequency bands, etc. Further, the illustration and description of certain filters, quantizers, etc., is exemplary; one of skill in the art will be able to select the appropriate elements that are appropriate for a particular application.

These and other variations upon the embodiments are intended to be covered by the present disclosure, which is limited only by the appended claims.

What is claimed is:

1. A circuit for removing noise due to a DC offset voltage in an amplifier from a signal frequency band, comprising:
an amplifier having a non-inverting input, an inverting input, and an output, the non-inverting input connected to a ground;
a first resistive device having a first end configured to receive an input signal in the signal frequency band and a second end connected to the inverting input of the amplifier;
a second resistive device having a first end connected to the output of the amplifier and a second end connected to the inverting input of the amplifier;
a third resistive device having a first end connected to the inverting input of the amplifier and a second end;
a two-position switch having a first end connected to the second end of the third resistive device and a second end connected to a ground, whereby the second end of the third resistive device is connected through the two-position switch to the ground when the switch is in a first position and not connected through the two-position switch to the ground when the switch is in a second position;
a single-bit sigma-delta modulator having an input connected to the output of the amplifier and an output, and configured to receive a sequence of clock edges and output a sequence of bits in response to the sequence of edges of a clock signal;
an exclusive-or element having a first input connected to the output of the sigma-delta modulator, a second input, and an output;
a switching signal source connected to the two-position switch and to the second input of the exclusive-or element and configured to provide a switching signal that opens and closes the two-position switch at a switching frequency not in the signal frequency band;
whereby any noise due to the DC offset voltage in the amplifier is moved out of the signal frequency band and to the switching frequency and harmonics thereof.

2. The circuit of claim 1 further comprising a sigma-delta filter having an input connected to the output of the exclusive-or element.

3. The circuit of claim 1 wherein:
the resistance of the third resistive device is of a value such that the two positions of the two-position switch result in two different noise gains of the circuit; and
the switching signal source is further configured to provide a duty cycle in which the ratio of the two positions of the two-position switch corresponds to the ratio of the different noise gains of the circuit whereby the two noise gains are canceled out in the frequency band of interest by the exclusive-or element.

4. A circuit for removing noise due to a DC offset voltage in an amplifier from a signal frequency band, comprising:
an amplifier having a non-inverting input, an inverting input, a non-inverted output and an inverted output;
a first resistive device having a first end configured to receive an input signal in the signal frequency band and a second end connected to the non-inverting input of the amplifier;
a second resistive device having a first end configured to receive an inverse of the input signal and a second end connected to the inverting input of the amplifier;
a third resistive device having a first end connected to the inverted output of the amplifier and a second end connected to the non-inverting input of the amplifier;
a fourth resistive device having a first end connected to the non-inverted output of the amplifier and a second end connected to the inverting input of the amplifier;
a fifth resistive device having a first end connected to the non-inverting input of the amplifier and a second end;
a two-position switch having a first end connected to the second end of the third resistive device and a second end connected to the inverting input of the amplifier, whereby the second end of the third resistive device is connected through the two-position switch to the inverting input of the amplifier when the switch is in a first position and not connected through the two-position switch to the inverting input of the amplifier when the switch is in a second position;
a single-bit sigma-delta modulator having a first input connected to the inverted output of the amplifier, a second input connected to the non-inverted output of the amplifier, and an output, and configured to receive a sequence of clock edges and output a sequence of bits in response to the sequence of edges of a clock signal;
an exclusive-or element having a first input connected to the output of the sigma-delta modulator, a second input, and an output;
a switching signal source connected to the two-position switch and to the second input of the exclusive-or element and configured to provide a switching signal that opens and closes the two-position switch at a switching frequency not in the signal frequency band;
whereby any noise due to the DC offset voltage in the amplifier is moved out of the signal frequency band and to the switching frequency and harmonics thereof.

5. The circuit of claim 1 further comprising a sigma-delta filter having an input connected to the output of the exclusive-or element.

6. The circuit of claim 4 wherein:
the resistance of the third resistive device is of a value such that the two positions of the two-position switch result in two different noise gains of the circuit; and
the switching signal source is further configured to provide a duty cycle in which the ratio of the two positions of the two-position switch corresponds to the ratio of the different noise gains of the circuit whereby the two noise gains are canceled out in the frequency band of interest by the exclusive-or element.

7. A circuit for removing noise due to a DC offset voltage in an amplifier from a signal frequency band, comprising:
an amplifier having a non-inverting input, an inverting input, and an output, the non-inverting input connected to a ground;
a first resistive device having a first end configured to receive an input signal in the signal frequency band and a second end connected to the inverting input of the amplifier;
a second resistive device having a first end connected to the output of the amplifier and a second end connected to the inverting input of the amplifier;
a third resistive device having a first end connected to the inverting input of the amplifier and a second end;
a two-position switch having a first end connected to the second end of the third resistive device and a second end connected to a ground, whereby the second end of the third resistive device is connected through the two-position switch to the ground when the switch is in a first position and not connected through the two-position switch to the ground when the switch is in a second position;
a switching signal source connected to the two-position switch and configured to provide a switching signal that opens and closes the two-position switch at a switching frequency not in the signal frequency band;
whereby any noise due to the DC offset voltage in the amplifier is moved out of the signal frequency band and to the switching frequency and harmonics thereof.

8. The circuit of claim 7 wherein:
the resistance of the third resistive device is of a value such that the two positions of the two-position switch result in two different noise gains of the circuit; and
the switching signal source is further configured to provide a duty cycle in which the ratio of the two positions of the two-position switch corresponds to the ratio of the different noise gains of the circuit whereby the two noise gains are canceled out in the frequency band of interest by the exclusive-or element.

9. A circuit for removing noise due to a DC offset voltage in an amplifier from a signal frequency band, comprising:
an amplifier having a non-inverting input, an inverting input, a non-inverted output and an inverted output;
a first resistive device having a first end configured to receive an input signal in the signal frequency band and a second end connected to the non-inverting input of the amplifier;
a second resistive device having a first end configured to receive an inverse of the input signal and a second end connected to the inverting input of the amplifier;
a third resistive device having a first end connected to the inverted output of the amplifier and a second end connected to the non-inverting input of the amplifier;
a fourth resistive device having a first end connected to the non-inverted output of the amplifier and a second end connected to the inverting input of the amplifier;
a fifth resistive device having a first end connected to the non-inverting input of the amplifier and a second end;
a two-position switch having a first end connected to the second end of the third resistive device and a second end connected to the inverting input of the amplifier, whereby the second end of the third resistive device is connected through the two-position switch to the inverting input of the amplifier when the switch is in a first position and not connected through the two-position switch to the inverting input of the amplifier when the switch is in a second position;
an adder configured to combine the inverting and non-inverting outputs of the amplifier;
a switching signal source connected to the two-position switch and configured to provide a switching signal that opens and closes the two-position switch at a switching frequency not in the signal frequency band;
whereby any noise due to the DC offset voltage in the amplifier is moved out of the signal frequency band and to the switching frequency and harmonics thereof.

10. The circuit of claim 9 wherein:
the resistance of the third resistive device is of a value such that the two positions of the two-position switch result in two different noise gains of the circuit; and
the switching signal source is further configured to provide a duty cycle in which the ratio of the two positions of the two-position switch corresponds to the ratio of the different noise gains of the circuit whereby the two noise gains are canceled out in the frequency band of interest by the exclusive-or element.
